(19) United States
(12) Patent Application Publication
(10) Pub. No.: US 2012/0208351 A1
(43) Pub. Date: Aug. 16, 2012

(54) CLEANING APPARATUS FOR SEMICONDUCTOR MANUFACTURING APPARATUS AND METHOD FOR MANUFACTURING SEMICONDUCTOR DEVICE USING THE SAME

(75) Inventors: Norikazu Nakamura, Kawasaki (JP); Atsushi Yamada, Kawasaki (JP); Masayuki Takeda, Kawasaki (JP); Keiji Watanabe, Kawasaki (JP); Kenji Imanishi, Kawasaki (JP)

(73) Assignee: FUJITSU LIMITED, Kawasaki (JP)

(21) Appl. No.: 13/357,887

(22) Filed: Jan. 25, 2012

(30) Foreign Application Priority Data
Feb. 15, 2011 (JP) 2011-030068

(51) Int. Cl. B08B 7/04; B08B 13/00; B08B 5/00; H01L 21/20

(52) U.S. Cl. 438/478; 156/345.1; 134/1.1; 134/31; 257/E21.09

(57) ABSTRACT

A cleaning apparatus for a semiconductor manufacturing apparatus includes: a oxide removal unit that removes an oxide over a surface of a deposit adhered to components of the semiconductor manufacturing apparatus, and a deposit removal unit that removes the deposit after the oxide over the surface is removed by the oxide removal unit.

### CROSS REFERENCE TO RELATED APPLICATION

This application is based upon and claims the benefit of priority from the prior Japanese Patent Application NO. 2011-030068 filed on Feb. 15, 2011, the entire contents of which are incorporated herein by reference.

### FIELD

The embodiments disclosed hereafter is related to a cleaning apparatus for a semiconductor manufacturing apparatus and a method for manufacturing a semiconductor device using the same.

### BACKGROUND

In recent years, an electronic device (compound semiconductor device), which is provided with a GaN layer and an AlGaN layer formed on and above a substrate in this order to use the GaN layer as an electron transit layer, has been actively developed. A GaN-based high electron mobility transistor (HEMT) is one of the compound semiconductor devices. A dense two-dimensional electron gas (2DEG) formed at a hetero-interface of AlGaN and GaN is used for the GaN-based HEMT.

GaN has a band gap of 3.4 eV, which is larger than a band gap of Si (1.1 eV) and a bang gap of GaAs (1.4 eV). In other words, GaN has a high breakdown field strength. GaN also has a high electron saturation velocity. Thus, GaN is highly promising as a material of a compound semiconductor device capable of high-voltage operation and of providing high-power output. GaN is also highly promising as a material of a power supply device which allows power saving.

A compound semiconductor such as GaN is formed by metal organic vapor phase epitaxy (MOVPE) on a substrate such as a silicon substrate, a silicon carbide substrate, and a sapphire substrate. A semiconductor manufacturing apparatus, which is used to form a compound semiconductor film by MOVPE, has various components therein. When the film is formed, raw materials of the compound semiconductor are adhered to these components. Accordingly, the raw materials of the compound semiconductor are accumulated on the components when film forming processes are repeated. As the amount of the accumulated substance is increased, the adhered substance may be detached from the components due to stress relief. The detached substance may contaminate the inside of the semiconductor manufacturing apparatus, and also prevent favorable crystal growth. When the adhered substance is present inside of the semiconductor manufacturing apparatus, the outer skin of the adhered substance may be evaporated during crystal growth, floating in the semiconductor manufacturing apparatus and adhering to a wafer. At this time, favorable crystal growth is also prevented. Thus, it is important to appropriately clean the components inside of the semiconductor manufacturing apparatus.

As a method for cleaning the components, wet cleaning and dry cleaning are suggested. The dry cleaning is more preferable because the wet cleaning unavoidably leaves behind a slight amount of water on the components, which may be evaporated during film formation of the compound semiconductor. The dry cleaning has another advantage that only a material of interest may be selectively removed. In other words, by the dry cleaning, deposits may be removed without substantially etching the components.

However, dry cleaning of the components takes much time. Since the semiconductor manufacturing apparatus is not used unless the components are cleaned, the film formation of the compound semiconductor is not performed during the cleaning. Thus, the throughput of the semiconductor device manufacturing is reduced.

[Patent Document 1] Japanese Laid-Open Patent Publication No. 2003-282543

### SUMMARY

According to an aspect of the present invention, there is provided a cleaning apparatus for a semiconductor manufacturing apparatus includes a oxide removal unit that removes an oxide on a surface of a deposit adhered to components of the semiconductor manufacturing apparatus, and a deposit removal unit that removes the deposit after the oxide on the surface is removed by the oxide removal unit.

According to another aspect of the present invention, there is provided a method for cleaning a semiconductor manufacturing apparatus includes removing an oxide on a surface of a deposit adhered to components of the semiconductor manufacturing apparatus and removing the deposit after removing the oxide.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF THE DRAWINGS

FIG. 1 is a schematic view of a cleaning apparatus for a semiconductor manufacturing apparatus according to an embodiment;

FIG. 2 illustrates an example of components of the semiconductor manufacturing apparatus;

FIGS. 3A-3C are a cross-sectional view of a method for manufacturing a GaN-based HEMT in a sequence of steps;

FIGS. 4A-4B are a cross-sectional view of the method for manufacturing the GaN-based HEMT in a sequence of steps following the steps illustrated in FIGS. 3A-3C;

FIG. 5 illustrates an example of an outer appearance of a high output amplifier;

FIGS. 6A, 6B illustrates a power supply device;

FIGS. 7A, 7B illustrate a component to which a deposit is adhered;

FIGS. 8A, 8B illustrate a cleaned component according to an example; and

FIGS. 9A, 9B illustrate a cleaned component according to a comparative example.

### DESCRIPTION OF THE PREFERRED EMBODIMENTS

The reason why dry cleaning of components requests a long time are studied. As a result, the inventors found that deposits adhered to some components have oxidized surfaces. In light of the number of steps and cost, generally, the dry cleaning of the components is performed collectively after a predetermined number of components are reached for components to be cleaned. Accordingly, some components are stored in an ambient atmosphere for a long period of time before they are dry cleaned.

The surfaces of the deposits adhered to such components are gradually oxidized to produce oxide. Conventionally, the conditions of the dry cleaning are set in view of the constituent elements of a raw material of a compound semiconductor. However, it is difficult to remove the oxide under such conditions. For example, chlorine gas is normally used for dry cleaning. However, the oxide is physically stable and its reactivity with the chlorine gas is low. Accordingly, extended cleaning is needed to remove the oxide. A long time is therefore requested for dry cleaning according to the conventional technique.

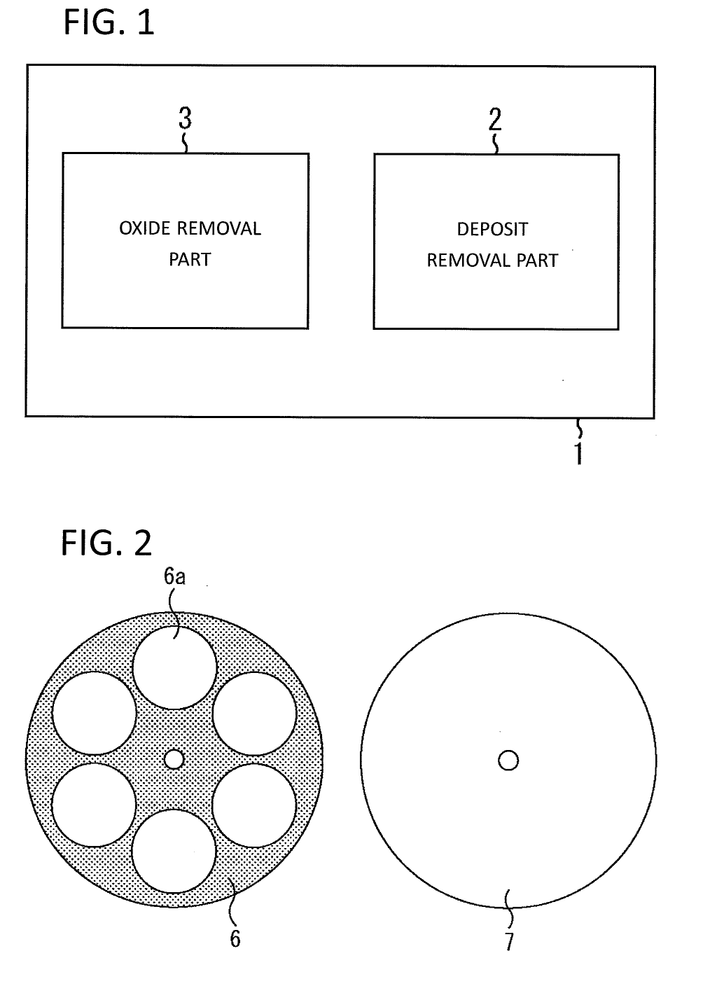

An embodiment of the present invention will be explained in detail below with reference to the accompanying drawings. FIG. 1 is a schematic view of a cleaning apparatus for a semiconductor manufacturing apparatus according to the embodiment.

A deposit removal part 2 for removing a deposit adhered to components of the semiconductor manufacturing apparatus and an oxide removal part 3 for removing an oxide on a surface of the deposit are provided in the cleaning apparatus 1 for the semiconductor manufacturing apparatus according to the embodiment. When a compound semiconductor device is manufactured using GaN, AlGaN, and AlN as raw materials, its deposit contains at least one of GaN, AlGaN, and AlN as a nitride semiconductor.

For example, a plasma processing device is used as the oxide removal part 3 for exposing the components in a chamber to plasma of an inert gas. In other words, the oxide removal part 3 performs plasma-etching on the oxide. An argon gas may be used as the inert gas. Alternatively, the argon gas may be mixed with a hydrogen gas to be used as the inert gas. The oxide removal part 3 is not limited to the plasma processing device. For example, the oxide removal part 3 may be a device for performing a bead blasting treatment or a device for polishing the surface of the deposit. The oxide on the surface of the deposit is saturated when its thickness is approximately 10 nm. Accordingly, it is only requested that the oxide removal part 3 may remove the oxide having the thickness of approximately 10 nm.

For example, a dry cleaning apparatus for performing a dry processing such as chemical reaction etching is used as the deposit removal part 2. As an etching gas, at least one of a hydrogen gas, chlorine gas, and hydrogen chloride gas may be used.

The semiconductor manufacturing apparatus and its components to be cleaned by the cleaning apparatus 1 are not limited thereto. For example, the semiconductor manufacturing apparatus may be a MOVPE device, and its components may be a susceptor cover 6 as illustrated in FIG. 2A and a ceiling plate 7 as illustrated in FIG. 2B. Wafer holding sections 6a are provided on the susceptor cover 6. The susceptor cover 6 may be made of carbon coated with SiC, and the ceiling plate 7 may be made of quartz. However, materials of the components are not limited thereto.

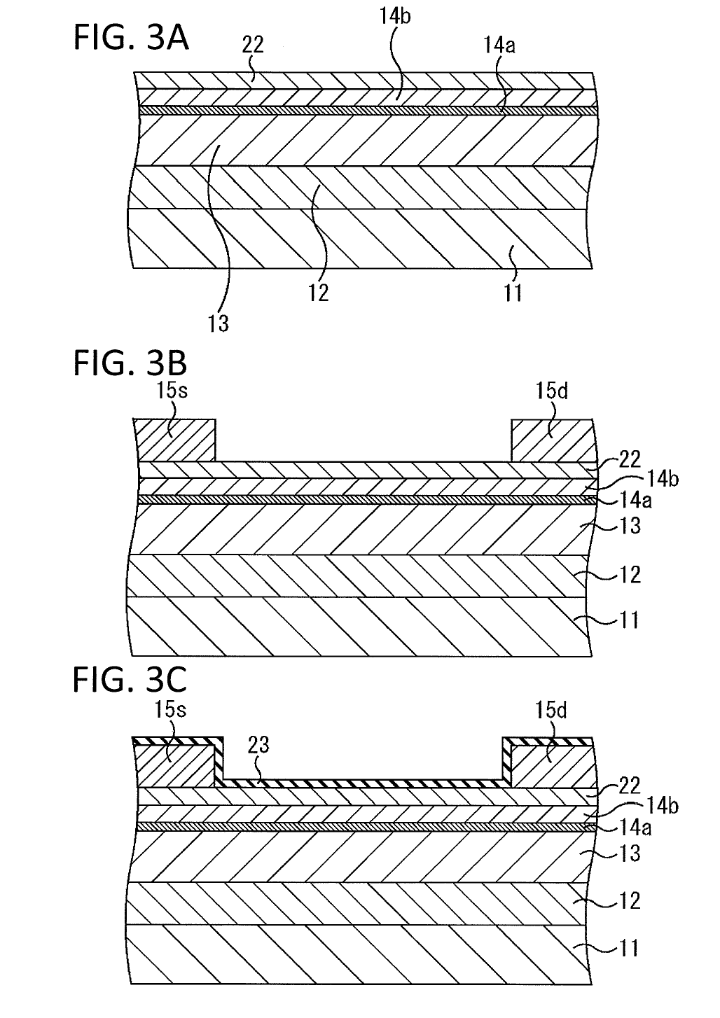

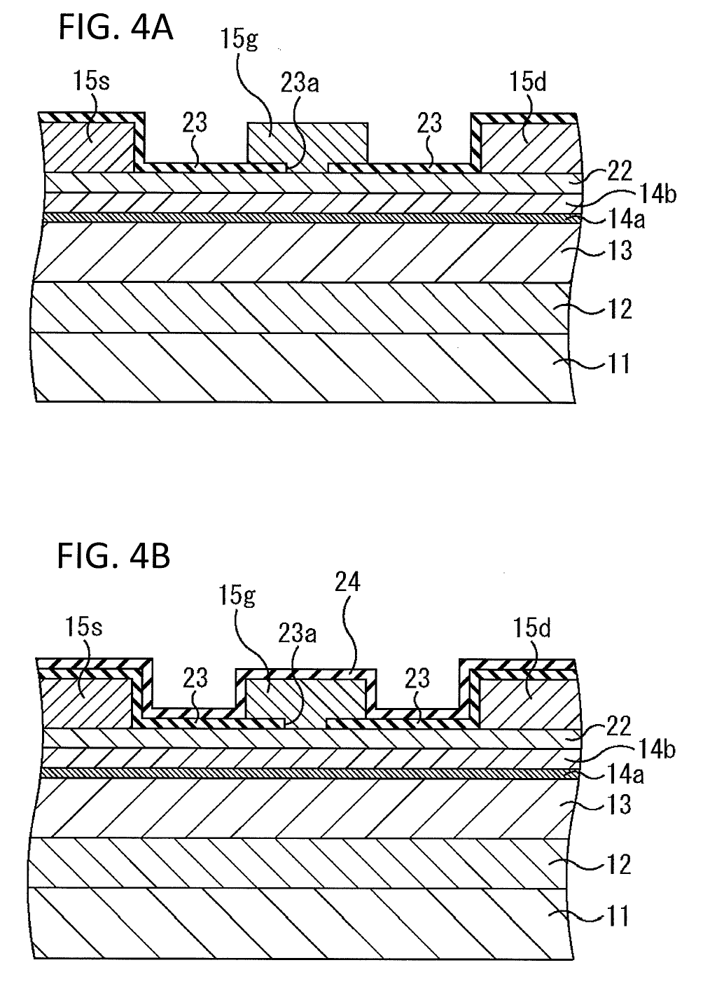

Next, a method for manufacturing a semiconductor device using the semiconductor manufacturing apparatus to be cleaned by the cleaning apparatus 1 and a method for cleaning the semiconductor manufacturing apparatus using the cleaning apparatus 1 will be explained below. FIGS. 3A-3C and FIGS. 4A-4B are cross-sectional views of a method for manufacturing a GaN-based HEMT (compound semiconductor device) in a sequence of steps according to the embodiment.

First, with reference to FIG. 3A, a buffer layer 12, an i-GaN layer 13, an i-AlGaN layer 14a, an n-AlGaN layer 14b, and an n-GaN layer 22 are formed on a Si substrate 11. An AlN layer or AlGaN layer is formed as the buffer layer 12. Alternatively, the AlGaN layer may be formed on the AlN layer to serve as the buffer layer 12. The buffer layer 12, the i-GaN layer 13, the i-AlGaN layer 14a, the n-AlGaN layer 14b, and the n-GaN layer 22 are formed by crystal growth such as a MOVPE method. At this time, these layers may be sequentially formed by selecting raw material gas. As a raw material of aluminium (Al) and as a raw material of gallium (Ga), trimethylaluminum (TMA) and trimethylgallium (TMG) may be respectively used. As a raw material of nitrogen (N), ammonia (NH₃) may be used. Also, as a raw material of silicon (Si) contained in the n-AlGaN layer 14b and the n-GaN layer 22 as an impurity, silane (SiH₄) may be used.

With reference to FIG. 3B, a source electrode 15s and a drain electrode 15d are formed on the n-GaN layer 22 by a lift-off method after the n-GaN layer 22 is formed. For forming the source electrode 15s and the drain electrode 15d, a resist pattern that opens a region where the source electrode 15s and the drain electrode 15d are to be formed is formed and Ti and Al are deposited thereon. Then, the resist pattern and Ti and Al deposited thereon are removed. Subsequently, ohmic contact is formed by thermal processing in nitrogen gas at 400 to 1000 degrees C. (for example, 600 degrees C.).

Next, with reference to FIG. 3C, a passivation film 23 is formed on the n-GaN layer 22 to cover the source electrode 15s and the drain electrode 15d. As the passivation film 23, a silicon nitride film may be formed by plasma chemical vapor deposition (CVD).

Then, a resist pattern that opens a region where an opening 23a is to be formed is formed. By etching using the resist pattern, the opening 23a is formed on the passivation film 23 as illustrated in FIG. 4A. Subsequently, a gate electrode 15g, which is in contact with the n-GaN layer 22 via the opening 23a, is formed on the passivation film 23 by the lift-off method. After the resist pattern used for forming the opening 23a is removed, another resist pattern that opens a region where the gate electrode 15g is to be formed is formed. Ni and Au are deposited thereon, and then the resist pattern and Ni and Au deposited thereon are removed, so that the gate electrode 15g is formed.

With reference to FIG. 4B, a passivation film 24 is formed on the passivation film 23 to cover the gate electrode 15g. As the passivation film 24, a silicon nitride film is formed by a plasma CVD method.

Then, a gate wire connecting a plurality of gate electrodes 15g, a source wire connecting a plurality of source electrodes 15s, and a drain wire connecting a plurality of drain electrodes 15d are formed. Consequently, the GaN-based HEMT may be obtained.

When the semiconductor device is manufactured according to the method as described above, a deposit is ineluctably adhered to the components of the semiconductor manufacturing apparatus (for example, MOVPE device) used for forming the nitride semiconductor (compound semiconductor) such as the buffer layer 12, the i-GaN layer 13, the i-AlGaN layer 14a, the n-AlGaN layer 14b, and the n-GaN layer 22. Thus, the components of the semiconductor manufacturing apparatus are cleaned every time a predetermined number of treatments are terminated.

For cleaning the components, the components are firstly conveyed to the oxide removal part 3 and exposed to a plasma of an argon gas, so that the surface of the deposit is subjected to plasma treatment. Consequently, the oxide is removed even when the oxide is present on the surface of the deposit. The condition of the plasma treatment is not limited thereto. However, the condition is set so that the oxide having the thickness of approximately 10 nm may be removed when the oxide is present on the surface of the deposit. It is because the oxide is saturated when its thickness is approximately 10 nm even when the oxide is generated on the surface of the deposit before the cleaning is started. The components themselves are hardly damaged by the plasma treatment.

Next, the components are conveyed to the deposit removal part 2 to separate the deposit from the components by dry etching using hydrogen chloride gas. Even when the oxide is generated on the surface of the deposit before the cleaning is started, the oxide is removed at the oxide removal part 3. Thus, the deposit may be quickly separated. The components themselves are hardly damaged by such dry cleaning.

As described above, the components may be promptly cleaned. In other words, the components may be cleaned efficiently for a short time.

Incidentally, it is preferable that the components to be cleaned are kept away from an ambient atmosphere during the period from the termination of the treatment at the oxide removal part 3 to the start of the treatment at the deposit removal part 2. Thus, it is preferable that air in the chamber of the oxide removal part 3 is sufficiently exhausted after the treatment at the oxide removal part 3 is terminated and then the components are conveyed to the chamber of the deposit removal part 2 partitioned by the load lock chamber to start the treatment at the deposit removal part 2.

The compound semiconductor device may be provided by a monolithic microwave integrated circuit (MMIC) by mounting a resistor and a capacitor on the Si substrate 11.

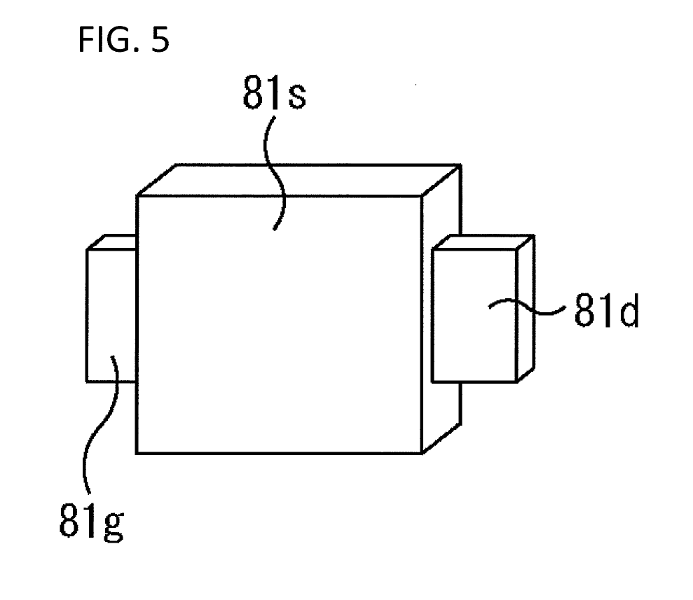

The GaN-based HEMT may be used as a high output amplifier. FIG. 5 illustrates an example of the outer appearance of the high output amplifier. According to this example, a source terminal 81s connected to a source electrode is provided on a surface of a package. A gate terminal 81g connected to a gate electrode and a drain terminal 81d connected to a drain electrode extend from sides of the package.

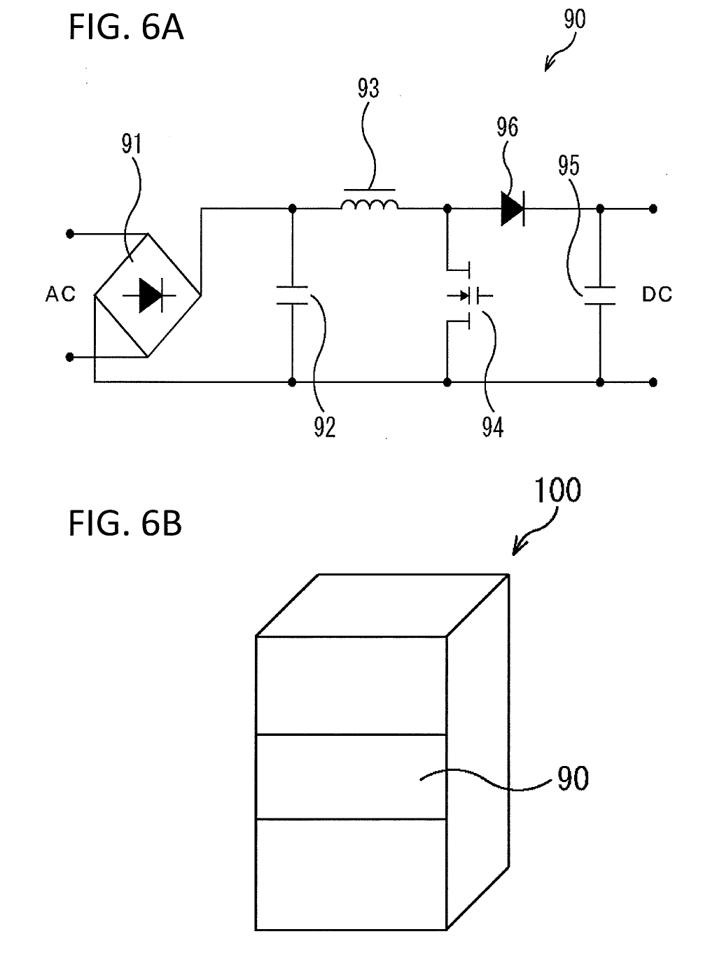

The GaN-based HEMT according to this embodiment may be also used as a power supply device. FIG. 6A illustrates a PFC (power factor correction) circuit, and FIG. 6B illustrates a server power supply (power supply device) including the PFC circuit as illustrated in FIG. 6A.

With reference to FIG. 6A, the PFC circuit 90 includes a capacitor 92 connected to a diode bridge 91 to which an alternating-current power supply (AC) is connected. One terminal of a choke coil 93 is connected to one terminal of the capacitor 92, and the other terminal of the choke coil 93 is connected to one terminal of a switching element 94 and an anode of a diode 96. The switching element 94 corresponds to the HEMT according to the embodiment, and its one terminal corresponds to the drain electrode of the HEMT according to the embodiment. The other terminal of the switching element 94 corresponds to the source electrode of the HEMT according to the embodiment. One terminal of a capacitor 95 is connected to a cathode of the diode 96. The other terminal of the capacitor 92, the other terminal of the switching element 94, and the other terminal of the capacitor 95 are grounded. A direct-current power supply (DC) is taken out between the terminals of the capacitor 95.

With reference to FIG. 6B, the PFC circuit 90 is incorporated into the server power supply 100.

A power supply device capable of high-speed operation may be formed in a similar manner as the server power supply 100. Also, a switching element formed like the switching element 94 may be used for a switching power supply or an electronic device. Further, these semiconductor devices may be used as components for a full-bridge power supply circuit such as a server power supply circuit.

Next, experiments conducted by the present inventors will be explained below.

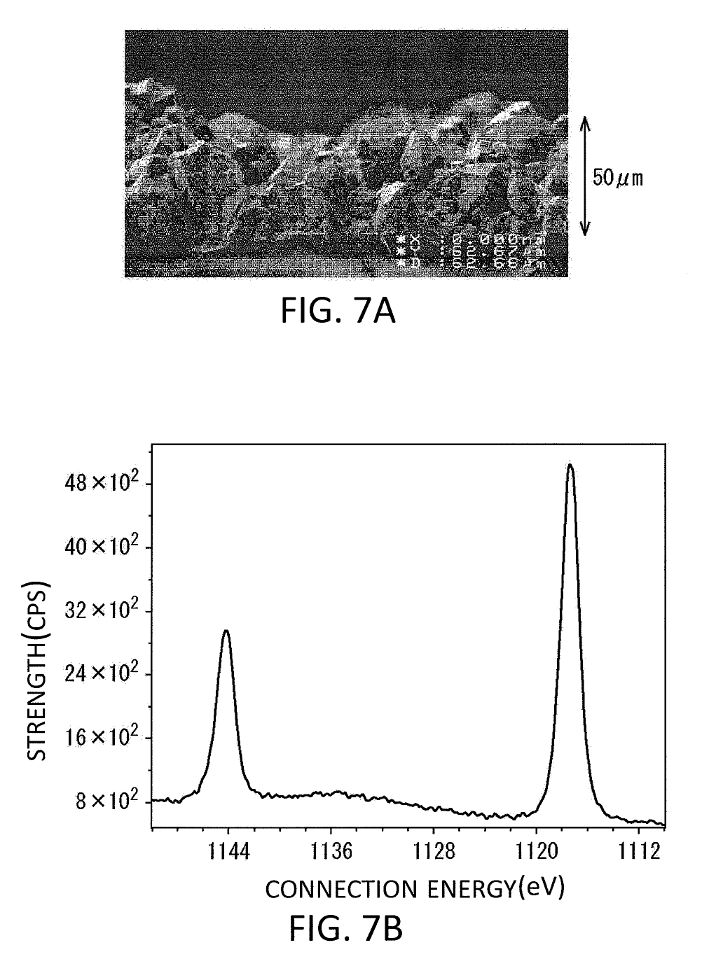

First, a GaN layer was repeatedly formed using the semiconductor manufacturing apparatus by metalorganic vapor phase epitaxy (MOVPE). Then, the components of the semiconductor manufacturing apparatus were imaged by a scanning electron microscope (SEM). FIG. 7A is the SEM image. As illustrated in FIG. 7A, a deposit having the thickness of 50 to 80 μm was observed. Also, the strength of Ga2p was measured by X-ray photoelectron spectroscopy. The measurement result is illustrated in FIG. 7B. It was found from FIG. 7B that the deposit contains Ga atoms.

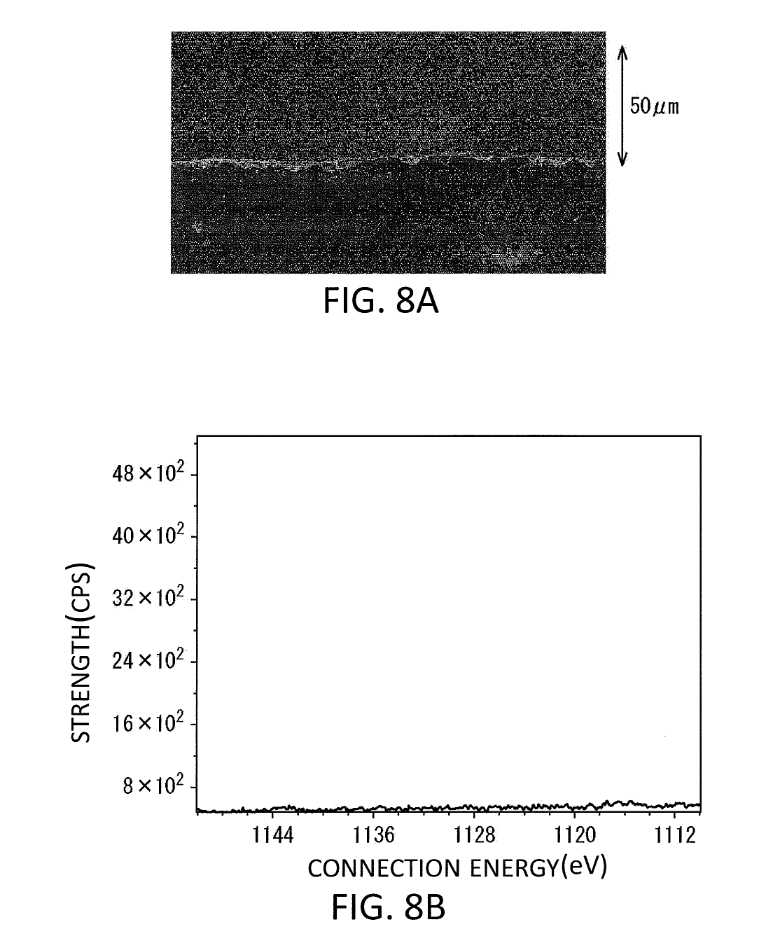

Next, components of the semiconductor manufacturing apparatus were cleaned using the cleaning apparatus 1 according to the embodiment (example). For cleaning the components, the treatment at the deposit removal part 2 was conducted after the treatment at the oxide removal part 3 was conducted. At the oxide removal part 3, argon gas was supplied at the flow rate of 20 sccm into the chamber to which the components are conveyed. An argon plasma was generated under a discharge output of 200 W and a chamber pressure of 10 mTorr. Then, the oxide on the surface of the deposit was removed. At the deposit removal part 2, hydrogen chloride gas was introduced into the chamber to which the components were conveyed at the flow rate of 2 l/m at high temperature of 900 degrees C. to perform dry cleaning. The dry cleaning was performed for one hour. Then, the components were imaged by the SEM after the dry cleaning. FIG. 8A illustrates the SEM image. As illustrated in FIG. 8A, the deposit was not observed. Also, the strength of Ga2p was measured by X-ray photoelectron spectroscopy. The measurement result was illustrated in FIG. 8B. It was also found from FIG. 8B that there is no deposit.

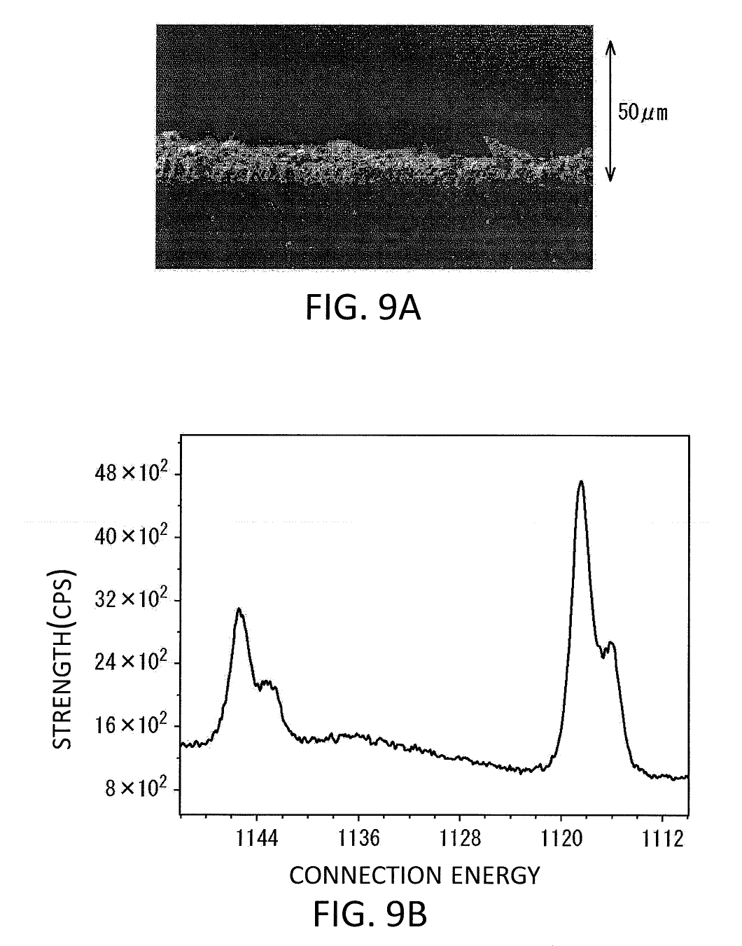

For comparison, the components to which the deposit is adhered by repeatedly forming the GaN layer as described above were cleaned without the treatment for removing the oxide (comparative example). In the other words, the dry cleaning was conducted under the same condition as described above without removing the oxide. However, the dry cleaning was conducted for two hours. The components were imaged by the SEM after the dry cleaning. FIG. 9A illustrates the SEM image. As illustrated in FIG. 9A, the deposit having the thickness of 10 to 20 μm was observed. The amount of the deposit was reduced, but approximately 20% of the deposit was present even after the dry cleaning. Also, the strength of Ga2p was measured by X-ray photoelectron spectroscopy. The measurement result was illustrated in FIG. 9B. It was found from FIG. 9B that the deposit containing Ga atoms remains.

From the result of the experiments, the components may be cleaned with high removal efficiency for a short time by using the cleaning apparatus 1 according to the embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a depicting of the superiority and inferiority of the invention. Although the embodiments of the present invention have been described in detail, it should be understood that the various changes, substitutions, and alterations could be made hereto without departing from the spirit and scope of the invention.

What is claimed is:

1. A cleaning apparatus for a semiconductor manufacturing apparatus, comprising:
a oxide removal unit that removes an oxide over a surface of a deposit adhered to components of the semiconductor manufacturing apparatus, and
a deposit removal unit that removes the deposit after the oxide over the surface is removed by the oxide removal unit.

2. The cleaning apparatus for the semiconductor manufacturing apparatus according to claim 1, wherein the oxide removal unit performs plasma etching over the oxide.

3. The cleaning apparatus for the semiconductor manufacturing apparatus according to claim 2, wherein the oxide removal unit exposes the oxide to plasma of inert gas for the plasma etching.

4. The cleaning apparatus for the semiconductor manufacturing apparatus according to claim 1, wherein the deposit removal unit performs chemical reaction etching over the deposit.

5. The cleaning apparatus for the semiconductor manufacturing apparatus according to claim 4, wherein the deposit removal unit uses at least one of hydrogen gas, chlorine gas, and hydrogen chloride gas as etching gas for the chemical reaction etching.

6. The cleaning apparatus for the semiconductor manufacturing apparatus according to claim 1, wherein the components, the treatment for which by the oxide removal unit is terminated, is conveyed to the deposit removal unit while being kept away from an ambient atmosphere.

7. The cleaning apparatus for the semiconductor manufacturing apparatus according to claim 1, wherein the deposit contains a nitride semiconductor.

8. The cleaning apparatus for the semiconductor manufacturing apparatus according to claim 7, wherein the nitride semiconductor contains at least one of GaN, AlGaN, and AlN.

9. The cleaning apparatus for the semiconductor manufacturing apparatus according to claim 1, wherein the components of the semiconductor manufacturing apparatus contain at least one of quartz, silicon carbide, and carbon.

10. A method for cleaning a semiconductor manufacturing apparatus, comprising:
removing an oxide over a surface of a deposit adhered to components of the semiconductor manufacturing apparatus; and
removing the deposit after removing the oxide.

11. The method for cleaning the semiconductor manufacturing apparatus according to claim 10, wherein plasma etching is performed over the oxide in removing the oxide.

12. The method for cleaning the semiconductor manufacturing apparatus according to claim 11, wherein the oxide is exposed to plasma of inert gas for the plasma etching.

13. The method for cleaning the semiconductor manufacturing apparatus according to claim 1, wherein chemical reaction etching is performed over the deposit in removing the deposit.

14. The method for cleaning the semiconductor manufacturing apparatus according to the claim 13, wherein at least one of hydrogen gas, chlorine gas, and hydrogen chloride gas is used as etching gas for the chemical reaction etching.

15. The method for cleaning the semiconductor manufacturing apparatus according to claim 10, wherein the components, the oxide of which is removed, is conveyed to a chamber for removing the deposit while being kept away from an ambient atmosphere.

16. The method for cleaning the semiconductor manufacturing apparatus according to claim 10, wherein the deposit contains a nitride semiconductor.

17. The method for cleaning the semiconductor manufacturing apparatus according to claim 16, wherein the nitride semiconductor contains at least one of GaN, AlGaN, and AlN.

18. The method for cleaning the semiconductor manufacturing apparatus according to claim 10, wherein the components contain at least one of quartz, silicon carbide, and carbon.

19. A method for manufacturing a semiconductor device, comprising;
forming a nitride semiconductor layer above a substrate using a semiconductor manufacturing apparatus; and
cleaning components of the semiconductor manufacturing apparatus by the cleaning apparatus for a semiconductor manufacturing apparatus, wherein the cleaning apparatus comprises:
a oxide removal unit that removes an oxide over a surface of a deposit adhered to components of the semiconductor manufacturing apparatus, and
a deposit removal unit that removes the deposit after the oxide over the surface is removed by the oxide removal unit.
